(19) United States
(12) Patent Application Publication
(10) Pub. No.: US 2025/0109480 A1
(43) Pub. Date: Apr. 3, 2025

(54) LOW-DIELECTRIC-CONSTANT POLYMER SUBSTRATE AND MANUFACTURING METHOD THEREFOR

(71) Applicant: KOREA INSTITUTE OF MATERIALS SCIENCE, Changwon-si, Gyeongsangnam-do (KR)

(72) Inventors: Sung-hoon JUNG, Changwon-si, Gyeongsangnam-do (KR); Do-geun KIM, Changwon-si, Gyeongsangnam-do (KR); Seung-hoon LEE, Changwon-si, Gyeongsangnam-do (KR); Joo-young PARK, Changwon-si, Gyeongsangnam-do (KR); Eun-yeon BYEON, Changwon-si, Gyeongsangnam-do (KR); Jun-yeong YANG, Changwon-si, Gyeongsangnam-do (KR)

(21) Appl. No.: 18/717,554

(22) PCT Filed: Dec. 10, 2021
(86) PCT No.: PCT/KR2021/018783

§ 371 Date: Jun. 7, 2024

(30) Foreign Application Priority Data
Dec. 9, 2021 (KR) 10-2021-0176081

(51) Int. Cl. C23C 14/20; C23C 14/02

(52) U.S. Cl. CPC C23C 14/205; C23C 14/022

(57) ABSTRACT

The present disclosure provides a low dielectric polymer substrate and a preparation method thereof. More specifically, the present disclosure provides a low dielectric polymer substrate to which metal or ceramic may be deposited with high adhesion without a separate adhesive layer through surface modification of a polymer substrate and a preparation method thereof.

### TECHNICAL FIELD

The present disclosure relates to a low dielectric polymer substrate and a preparation method thereof. More specifically, the present disclosure relates to a low dielectric polymer substrate to which metal or ceramic can be deposited by a high adhesion without a separate adhesive layer through surface modification of the polymer substrate and a preparation method thereof.

### DESCRIPTION OF RELATED ART

As demands for high-performance, high-speed transmission, miniaturization, light weight, and thinness of an electronic product increase, interests in not only a core component, a Flexible Printed Circuit Board (FPCB), but also a core material of FPCB, Flexible Copper Clad Laminated Substrate (FCCL), are also increasing.

A Flexible Copper Clad Laminated Substrate is an excellent material formed by laminating copper clad on one side or both sides of a polymer film in the aspect of flexibility of the material, such as bending resistance. In a conventional Flexible Copper Clad Laminated Substrate, copper has been deposited after formation of a layer of metal, such as Nickel, Chromium, and Titanium on a polymer film, to improve adhesion to the metal on the polymer substrate. A Flexible Copper Clad Laminated Substrate requires a separate step of etching for subsequently forming a pattern. However, there has been a problem that a Flexible Copper Clad Laminated Substrate of the above structure may have a polymer film peeled from a metal layer and a copper deposition layer during processes, such as a high temperature process. In addition, there has been a problem that thickness of a Flexible Copper Clad Laminated Substrate, of which flexibility and bending resistance are important, increases.

In addition to the demands and trends of the said electronic products, a low dielectric material which has low signal loss rate is important in 5G and post-5G telecommunications market, which requires a high-speed transfer of large-scale data in high frequency bands. Accordingly, a polymer substrate having low dielectric that is applicable to a Flexible Copper Clad Laminated Substrate, a telecommunication device, such as an antenna for high-speed communication, or a server board have been continuously developed.

Specifically, due to a hydrophobic property, a polymer having fluorine among polymers having low dielectric generally has low adhesion to a polymer substrate despite of formation of a thin metal film on a polymer substrate. Therefore, there have been efforts, such as pretreatment of surface of a polymer substrate with ultraviolet rays, to form adhesion to a thin film formed on a polymer substrate. However, there has been a problem in limitation of usability that it is difficult to significantly improve adhesion.

Accordingly, it is needed to develop a low dielectric polymer substrate that has not only thinner thickness and but also excellent adhesion to a coated layer while it has low dielectric.

As background of the present disclosure, a surface treatment method of a fluorine-containing resin and a surface treatment device of a fluorine-containing resin is described in Japanese Patent No. 6076844.

### SUMMARY

An object of the present disclosure is to provide a low dielectric polymer substrate with advanced adhesion between a polymer layer and a metal or ceramic coated layer.

Another object of the present disclosure is to provide a preparation method of a low dielectric polymer substrate to efficiently prepare a low dielectric polymer substrate with advanced adhesion between a polymer layer and a metal layer.

Another object of the present disclosure is to provide a preparation method of a low dielectric polymer substrate with a shortened preparation process.

Other purposes and advantages of the present disclosure should be clearly understood from the detailed description, claims and figures.

According to one aspect, it is provided a low dielectric polymer substrate including a low dielectric polymer layer; a surface modified layer formed by ion beam pretreatment of the surface of the polymer layer; and a metal or ceramic coated layer optionally formed on the surface modified layer, wherein a water contact angle of the surface modified layer is 90° or less.

According to one embodiment, the low dielectric polymer layer may include at least one species of Polytetrafluoroethylene (PTFE), Perfluoroalkoxy (PFA), Ethylene Tetrafluoroethylene (ETFE), Fluorinated Ethylene Propylene (FEP), Polyvinylidene Fluoride (PVDF), Modified polyimide (MPI), Polyphenylene Sulfide (PPS), Olefin, and Liquid crystal polymer (LCP).

According to one embodiment, dielectric constant of the low dielectric polymer layer may be 4 or less.

According to one embodiment, the low dielectric polymer layer may have thickness of 0.01 mm or more to less than 2 mm.

According to one embodiment, the ion beam pretreatment may be an ion beam pretreatment that uses hydrogen gas; helium gas; or argon gas and hydrogen gas.

According to one embodiment, the metal may be at least one species of Cu, Ni, Cr and Ti.

According to one embodiment, the ceramic may be at least one species of ZnO and Indium tin oxide (ITO).

According to another aspect, a product including the low dielectric polymer substrate described in the present disclosure is provided.

According to another aspect, a preparation method of a low dielectric polymer substrate including ion beam pretreating for surface modification of a surface of a low dielectric polymer layer; and optionally forming a metal or ceramic coated layer on the polymer layer, wherein ion beam energy of the ion beam pretreating is 50 to 2000 eV, is provided.

According to one embodiment, the low dielectric polymer layer in the preparation method of a low dielectric polymer substrate of the present disclosure may include at least one species of Polytetrafluoroethylene (PTFE), Perfluoroalkoxy (PFA), Ethylene tetrafluoroethylene (ETFE), Fluorinated Ethylene Propylene (FEP), Polyvinylidene Fluoride (PVDF), Modified Polyimide (MPI), Polyphenylene Sulfide (PPS), Olefin and Liquid crystal polymer (LCP).

According to one embodiment, gas used for the ion beam pretreating in the preparation method of a low dielectric polymer substrate of the present disclosure may be hydrogen gas; helium gas; or argon gas and hydrogen gas.

According to one embodiment, when the gas used for the ion beam pretreating in the preparation method of a low dielectric polymer substrate of the present disclosure is hydrogen, applied electrical power per ion beam speed may be 2 kW/mpm or less.

According to one embodiment, when the thickness of the low dielectric polymer layer in the preparation method of a low dielectric polymer substrate of the present disclosure is 0.01 or more to less than 2 mm, applied voltage for the ion beam pretreating may be 0.5 or more to less than 2 kV.

According to one embodiment, the metal or ceramic coated layer in the preparation method of a low dielectric polymer substrate of the present disclosure may be formed by sputtering deposition or ion beam assisted sputtering deposition.

According to one embodiment, the preparation method of a low dielectric polymer substrate of the present disclosure may proceed in a roll-to-roll processing manner.

According to one embodiment, the processing rate of the role-to-role processing in the preparation method of a low dielectric polymer substrate of the present disclosure may be 0.1 to 10 mpm.

According to one embodiment, a low dielectric polymer substrate with excellent adhesion between the polymer layer and the metal or ceramic coated layer by controlling conditions of ion beam pretreatment may be provided.

According to one embodiment, a low dielectric polymer substrate with excellent adhesion between the polymer layer and the metal or ceramic coated layer by controlling conditions of ion beam pretreatment may be efficiently prepared.

According to one embodiment, a low dielectric polymer substrate may be prepared by a shortened preparation process through ion beam pretreatment without requiring a separate formation of an adhesive layer.

### BRIEF DESCRIPTION OF THE DRAWINGS

FIG. 1 is a diagram schematically illustrating the low dielectric polymer substrate according to one embodiment of the present disclosure.

FIG. 2 is a diagram schematically illustrating the preparation method of a low dielectric polymer substrate of Example 1 according to one embodiment of the present disclosure.

FIG. 3 is a diagram schematically illustrating the preparation method of a low dielectric polymer substrate of Comparative Examples 1 to 3 of the present disclosure.

FIG. 4 is a diagram schematically illustrating the preparation method of a low dielectric polymer substrate of Comparative Example 4 of the present disclosure.

FIG. 5 is a graph showing the water contact angle of the low dielectric polymer substrate with formation of the surface modified layer according to one embodiment of the present disclosure.

FIG. 6 are images showing surface shape according to applied electrical power per speed of hydrogen gas ion beam according to one embodiment of the present disclosure.

FIG. 7 is a graph showing the results of surface component analysis of the low dielectric polymer substrates with the formed surface modified layers according to one embodiment of the present disclosure.

FIG. 8 is an image showing the surface structure of the metal layer of the low dielectric polymer substrate according to one embodiment of the present disclosure.

FIG. 9 is a graph showing test results of adhesion of the low dielectric polymer substrate according to one embodiment of the present disclosure.

FIG. 10 is an image showing Cross Cut test results of the low dielectric polymer substrate according to one embodiment of the present disclosure.

FIG. 11 is a diagram schematically illustrating 90° peeling test method of the low dielectric polymer substrate according to one embodiment of the present disclosure.

FIG. 12 is an image of 90° peeling test results of the low dielectric polymer substrate according to one embodiment of the present disclosure.

### DETAILED DESCRIPTION

Terms used in the present disclosure are used merely for describing specific embodiments and are not intended to limit the present disclosure.

Singular expressions include plural expressions unless the context clearly indicates otherwise.

Terms, such as “include” or “have,” described in the present disclosure are merely for indicating presence of characteristics, numbers, steps, actions, elements, parts or combinations thereof. The terms should not be interpreted as preliminarily excluding possibilities of presence or addition of at least one other characteristic, number, action, element, part, or combination thereof.

In the specification, a description that a part “includes” an element refers that, unless there is a specific contrary description, the element may be further included, and other elements are not excluded. Also, in the entire specification, the description of being “on” an object refers to a state of being disposed above or below a part of the object and does not necessarily mean the state of being above based on the gravitational direction.

The present disclosure may be applied with various variations and have several embodiments. Accordingly, specific examples are illustrated in figures and explained in detail in the detailed descriptions. Nonetheless, these are not to limit the present disclosure to specific embodiments. Instead, these should be understood that the disclosure includes every variation, and equivalent to substituent included in the scope of ideas and technology of the present disclosure. In explanation of the present disclosure, when detailed descriptions about a related, known technology may obscure the gist of the present disclosure, the detailed descriptions thereof are omitted.

Terms, such as first and second, may be used for describing various components, and the components should not be limited by the said terms. The said terms are used merely for distinguished one component from other components.

Hereinafter, embodiments of the present disclosure are explained in detail with reference to the attached figures. In explanation with reference to the attached figures, the same or corresponding components shall be assigned with the same reference figure numeral, and redundant descriptions thereof shall be omitted.

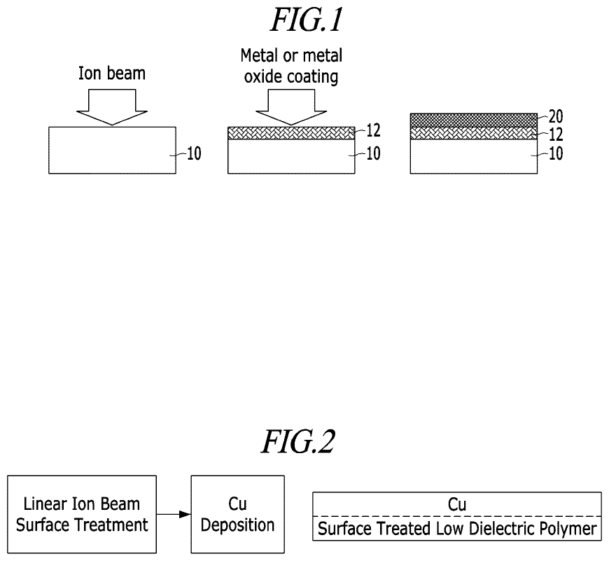

FIG. 1 is a diagram schematically illustrating the low dielectric polymer substrate of the present disclosure.

Referring to FIG. 1, according to one aspect of the present disclosure, it is provided a low dielectric polymer substrate including a low dielectric polymer layer 10; a surface modified layer 12 formed by ion beam pretreatment of the surface of the polymer layer 10; and a metal or ceramic coating layer 20 optionally formed on the surface modified layer 12, wherein a contact angle with water of the surface modified layer is 90° or less.

The low dielectric polymer layer 10 may be consisted of various known materials. Although not limited thereto, the low dielectric polymer layer 10 may include at least one species of Polytetrafluoroethylene (PTFE), Perfluoroalkoxy (PFA), Ethylene Tetrafluoroethylene (ETFE), Fluorinated Ethylene Propylene (FEP), Polyvinylidene Fluoride (PVDF), Modified Polyimide (MPI), Polyphenylene Sulfide (PPS), Olefin, and Liquid crystal Polymer (LCP).

Although not limited thereto, the dielectric constant of the low dielectric polymer layer may be 4 or less. According to the said configuration, as durability is also excellent and signal loss is minimized, it may be easily applicable to a telecommunication device, such as an antenna for high-speed communication, a server board, and a display.

Although not limited thereto, the thickness of the low dielectric polymer layer 10 may be 0.01 or more to less than 2 mm. According to the said configuration, as flexibility and bending resistance as well as durability are excellent, it may be easily applicable to a telecommunication device, such as an antenna for high-speed communication, a server board, and a display.

The surface modified layer 12 is formed by ion beam pretreatment. As the surface of the polymer layer 10 is modified by the ion beam pretreatment, adhesion to the metal or ceramic coated layer 20 may be improved even without a separate adhesive layer. A low dielectric polymer substrate may be characterized in that its surface energy increases and its water contact angle is low upon the surface modification by the ion beam pretreatment.

Although not limited thereto, it may be suitable for adhesive surface between the polymer layer 10 and the metal or ceramic coated layer 20 that the water contact angle of the surface modification layer 12 is 90° or less. It may be more suitable that the water contact angle of the surface modification layer 12 is 80° or less. It may be even more suitable that the water contact angle of the surface modification layer 12 is 70° or less. It may be even more suitable that the water contact angle of the surface modification layer 12 is 60° or less. It may be even more suitable that the water contact angle of the surface modification layer 12 is 50° or less. It may be even more suitable that the water contact angle of the surface modification layer 12 is 40° or less. It may be even more suitable that the water contact angle of the surface modification layer 12 is 30° or less. It may be even more suitable that the water contact angle of the surface modification layer 12 is 20° or less. It may be even more suitable that the water contact angle of the surface modification layer 12 is 10° or less. It may be even more suitable that the water contact angle of the surface modification layer 12 is less than 10°.

Although not limited thereto, the ion beam treatment may be ion beam treating that uses hydrogen gas; helium gas; or argon gas and hydrogen gas. The said configuration may be suitable for improvement of adhesiveness between the polymer layer 10 and the metal or ceramic coated layer 20, and ion beam pretreatment that uses argon gas and hydrogen gas may be more suitable.

Although not limited thereto, the metal may be at least one species of Cu, Ni, Cr and Ti.

Although not limited thereto, the ceramic may be at least one species of ZnO and Indium tin oxide (ITO).

Although not limited thereto, the metal or ceramic coated layer 20 may be formed on both sides of the polymer layer 10.

Although not limited thereto, the metal or ceramic coated layer 20 may be consisted of a single layer or multiple layers.

According to another aspect, a product including the dielectric polymer substrate described in the present disclosure is provided.

The product may be a product that requires flexibility, bending resistance, and low dielectric. Although not limited thereto, the product may be at least one species of a Flexible Copper Clad Laminated Substrate, an antenna for telecommunication, a telecommunication device, a server board, and a display.

According to another aspect, a preparation method of a low dielectric polymer substrate including ion beam pretreating for surface modification of the surface of the low dielectric polymer layer; and optionally forming a metal or ceramic coated layer on the polymer layer, wherein ion beam energy for the ion beam treating is 50 to 2000 eV, is provided.

The ion beam treating is a step of modifying a low dielectric polymer layer to increase adhesion to the coated layer. Here, the ion beam energy of 50 to 2000 eV may be suitable for increasing adhesion between the polymer layer and the metal or ceramic coated layer as surface energy increases. Ion beam energy of 50 to 1500 eV may be the more suitable. Ion beam energy of 50 to 1000 eV may be even more suitable. Ion beam energy of 50 to 500 eV may be the more suitable.

Although not limited thereto, when the ion beam energy is less than 50 eV, the effects by the surface modification may be insufficient, and when ion beam energy is over 2000 eV, the polymer layer may be deformed so that adhesion to the metal or ceramic coated layer may rather decrease.

Although not limited thereto, the low dielectric polymer layer in the preparation method of a low dielectric polymer substrate of the present disclosure may include at least one species of Polytetrafluoroethylene (PTFE), Perfluoroalkoxy (PFA), Ethylene Tetrafluoroethylene (ETFE), Fluorinated Ethylene Propylene (FEP), Polyvinylidene Fluoride (PVDF), Modified Polyimide (MPI), Polyphenylene Sulfide (PPS), Olefin, and Liquid crystal Polymer (LCP).

Although not limited thereto, the gas used for the ion beam pretreatment in the preparation method of a low dielectric polymer substrate of the present disclosure may be hydrogen gas; helium gas; or argon gas and hydrogen gas. The said configuration may be suitable for improvement of adhesion between the polymer layer and the metal or ceramic coated layer. It may be the more suitable to use argon gas and hydrogen gas. It may be even more suitable to process the ion beam treatment with hydrogen gas after processing ion beam treatment with argon gas.

Although not limited thereto, when the gas used for the ion beam pretreating in the preparation method of a low dielectric polymer substrate of the present disclosure is hydrogen, it may be suitable for increasing adhesion between the polymer layer and the metal or ceramic coated layer that the applied electric power per ion beam speed is 2 kW/mpm or less, and the more suitable that the applied electric power per ion beam speed is 1.7 kW/mpm or less.

Although not limited thereto, when the gas used for the ion beam pretreating in the preparation method of a low dielectric polymer substrate of the present disclosure is argon and hydrogen, it may be suitable for maintaining surface shape of the low dielectric polymer layer and improving adhesion to the coated layer that sum of applied electric powers of argon ion beam and hydrogen ion beam is 3 kW/mpm or less. It may be the more suitable that the sum is 2.5 kW/mpm or less.

Although not limited thereto, when the thickness of the low dielectric polymer layer is 0.01 or more to less than 2 mm in the preparation method of a low dielectric polymer substrate of the present disclosure, the applied voltage for the ion beam pretreating may suitably be 0.5 kV or more to less than 5 kV for improvement of adhesion and prevention of deformation of the polymer layer. The applied voltage for the ion beam pretreating may more suitably be 0.5 kV or more to less than 2 kV. When the thickness of the low dielectric polymer layer is relatively thin, deviation from the range of the applied voltage of 0.5 kV or more to less than 5 kV may result in reduced adhesion or deformation of the polymer layer.

Then, forming the metal or ceramic coated layer on the polymer layer in the preparation method of a low dielectric polymer substrate of the present disclosure, although not limited thereto, may have the metal or ceramic coated layer formed by sputtering deposition or ion beam assisted sputtering deposition. When the metal or ceramic coated layer is formed by ion beam assisted sputtering, the coated layer is formed denser so that its physical properties may be enhanced, and adhesion between the polymer layer and the coated layer may also be enhanced.

Although not limited thereto, the preparation method of a low dielectric polymer substrate of the present disclosure may proceed by role-to-role processing. Using role-to-role processing has an advantage that a large amount of a low dielectric polymer substrate over a large area may be prepared. Although not limited thereto, processing rate of the role-to-role processing may suitably be 0.1 to 10 mpm.

### EXAMPLE

Hereinafter, the present disclosure is described more specifically with examples and comparative examples of the present disclosure, and physical property evaluation results thereof.

### 1. Evaluation of Adhesion Between Low Dielectric Polymer Layer and Copper Coated Layer According to Ion Beam Pretreatment

### Example 1

FIG. 2 is a diagram schematically illustrating the preparation method of a low dielectric polymer substrate of Example 1 according to one embodiment of the present disclosure.

By using Ar gas, 2 mm thick surface of PTFE, a low dielectric polymer, was pretreated with a linear ion beam of 1.2 kV and speed of 1 mm/s, and a 300 nm thick Cu layer was deposited on the ion beam treated PTFE through DC sputter with power of 400 W to prepare the low dielectric polymer substrate of Example 1.

Subsequently, in order to evaluate adhesion between the PTFE substrate of a low dielectric polymer substrate and the Cu layer of Example 1, adhesion was evaluated using 90° Peeling Tester after plating a 10 μm Cu layer on the deposited Cu layer. As the result, the adhesion between the PTFE substrate and the Cu layer was demonstrated as 6 N/cm.

### Comparative Examples 1 to 3

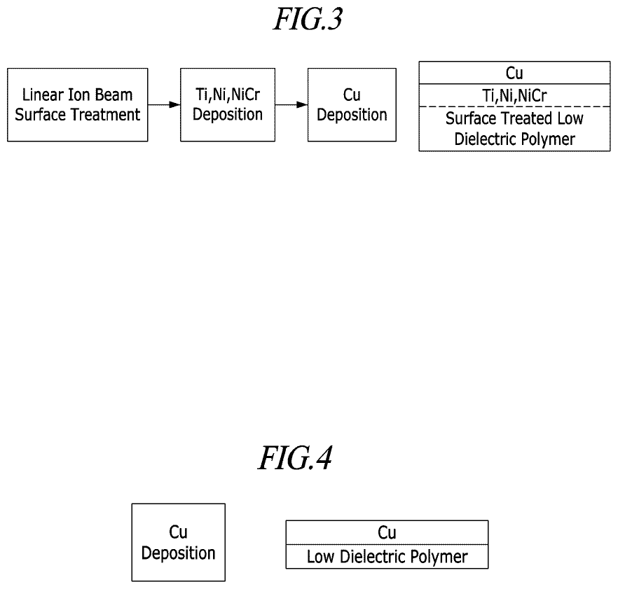

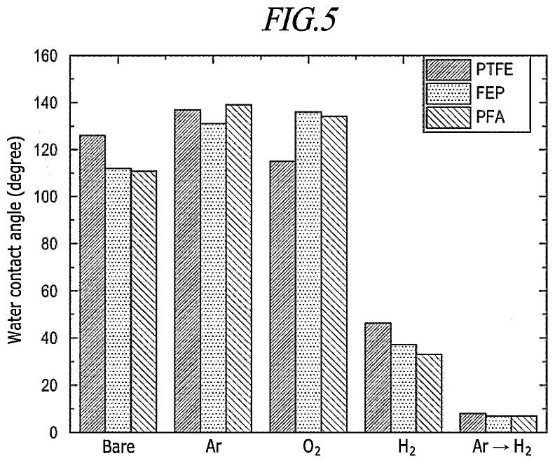

FIG. 3 is a diagram schematically illustrating the preparation method of a low dielectric polymer substrate of comparative examples 1 to 3 of the present disclosure.

By using Ar gas, 2 mm thick surface of PTFE, a low dielectric polymer, was pretreated with a linear ion beam of 1.2 kV and speed of 1 mm/s, an adhesive layer of Ti layer (Comparative Example 1), Cr layer (Comparative Example 2) or NiCr layer (Comparative Example 3) with thickness of 100 nm was deposited on the ion beam treated PTFE with power of 300 W, and a 300 nm thick Cu layer was deposited on the PTFE with deposition of Ti layer (Comparative Example 1), Cr layer (Comparative Example 2), or NiCr layer (Comparative Example 3) through DC sputter with power of 400 W to prepare a low dielectric polymer substrate of Comparative Examples 1 to 3.

Subsequently, in order to evaluate adhesion between the PTFE substrate of the low dielectric polymer substrate and the Cu layer in Comparative Examples 1 to 3, adhesion was evaluated using 90° Peeling Tester after plating a 10 μm Cu layer on the deposited Cu layer. As the result, the adhesions between the PTFE substrate and the Cu layer were demonstrated as 0.4 N/cm in Comparative Example 1, 0.5 N/cm in Comparative Example 2, and 3.6 N/cm in Comparative Example 3.

### Comparative Example 4

FIG. 4 is a diagram schematically illustrating a preparation method of a low dielectric polymer substrate of Comparative Example 4 of the present disclosure.

Without ion beam pretreatment, a 300 nm thick Cu layer was deposited on 2 mm thick surface of PTFE, a low dielectric polymer, through a DC sputter with power of 400 W to prepare Comparative Example 4.

Subsequently, in order to evaluate adhesion between the PTFE substrate of the low dielectric polymer substrate and the Cu layer in Comparative Example 4, adhesion is evaluated using 90° Peeling Tester after plating a 10 μm Cu layer on the deposited Cu layer. As the result, adhesion between the PTFE substrate and the Cu layer was demonstrated as 0.1 N/cm.

According to the said evaluation results of adhesion, it can be verified that adhesion between a low dielectric polymer layer and a metal coated layer is more enhanced when a metal coated layer is deposited after ion beam pretreatment on surface of a low dielectric polymer layer than either when ion beam treatment is not proceeded or when a metal coated layer is deposited after formation of an adhesive layer.

Therefore, the low dielectric substrate of the present disclosure can enhance adhesion between the low dielectric polymer layer and the coated layer without formation of a separate adhesive layer so that the preparation method thereof may also be shortened.

2. Evaluation of Water Contact Angle of Low Dielectric Polymer Layer Pretreated with Ion Beam Per Gas Type

A substrate of a low dielectric polymer, PTFE, FEP, or PFA, is prepared. While different types of gases are used on surface of each polymer substrate, ion beam pretreatment is proceeded under the following conditions to form a surface modified layer, and a water contact angle of surface of the polymer substrate with the surface modified layer formed is measured. Because ion beam energy used for formation of the surface modified layer is distributed in a range of 30% to 80% of anode voltage of ion beam generally in a form of Gaussian distribution, ion beam anode voltage of 0.6 to 1.2 kV is used for irradiating an ion beam to a specimen with a level of energy of 300 to 1000 eV.
1) Argon (Ar)
   1 kV, 70 mA, 0.6 mpm, 10 cycles, 1.17 kW/mpm
2) Oxygen (O₂)
   1 kV, 58 mA, 0.1 mpm, 2 cycles, 1.16 kW/mpm
3) Hydrogen (H₂)
   1 kV, 80 mA, 0.1 mpm, 2 cycles, 1.6 kW/mpm
4) Argon (Ar) and Hydrogen (H₂)
Argon (Ar): 0.6 kV, 26 mA, 0.1 mpm, 2 cycles, 0.31 kW/mpm
Hydrogen (H₂): 1.2 kV, 80 mA, 0.1 mpm, 2 cycles, 1.92 kW/mpm
Total 2.23 kW/mpm

FIG. 5 is a graph showing water contact angle of the low dielectric polymer substrate with formation of the surface modified layer according to one embodiment of the present disclosure.

Referring to FIG. 5, the contact angles between surface of the PTFE, FEP or PFA substrates treated with hydrogen ion beam and water are all 50° or less, and contact angles between surface of the PTFE, FEP or PFA substrates treated with hydrogen ion beam after argon ion beam treatment and water are all 10° or less. This is the result that shows that the above contact angles with water are significantly lower than the case of argon ion beam treatment or the case of oxygen ion beam treatment. That the water contact angle is significantly low shows that the surface energy is high. Due to the above, surface shape of the ion beam pretreated polymer layer may be changed less.

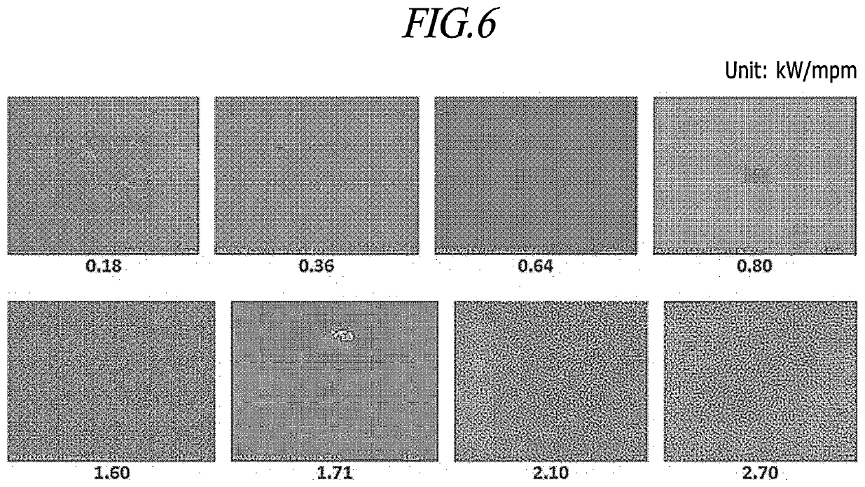

FIG. 6 is an image showing surface shape according to applied electrical power per speed of hydrogen gas ion beam according to one embodiment of the present disclosure.

Referring to FIG. 6, it can be shown that the surface shape of the low dielectric polymer substrate changes when the applied electrical power per speed of hydrogen gas ion beam is 2.1 kW/mpm or more. Accordingly, it may be suitable for hydrogen ion beam pretreatment that the applied electrical power per speed of ion beam is 2.0 kW/mpm or less.

Accordingly, it may be suitable for maintaining the flatness of surface shape to treat the low dielectric polymer substrate of the present disclosure, which is applicable to a Flexible Copper Clad Laminated Substrate, with hydrogen ion beam. It may be the more suitable for maintaining the flatness of surface shape to treat with hydrogen ion beam after treatment with argon ion beam.

3. Surface Component Analysis of Low Dielectric Polymer Pretreated with Ion Beam Per Gas Type

A substrate of PTFE, a low dielectric polymer, is prepared, and a surface modified layer is formed through ion beam pretreatment by using different types of gases on the surface of each PTFE substrate. Subsequently, a surface component analysis of the polymer substrate with the formation of the surface modified layer is proceeded by using X-ray photoelectron spectroscopy (XPS).

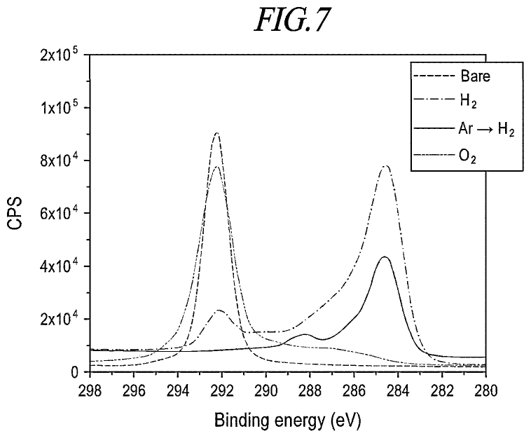

FIG. 7 is a graph showing the results of surface component analysis of the low dielectric polymer substrates with the formations of surface modified layers according to one embodiment of the present disclosure.

Referring to FIG. 7, when the PTFE surface is not pretreated with ion beam and when it is pretreated with oxygen ion beam, binding energy for CF binding of fluorine-based polymer peaked at 292 eV. On the other hand, when the PTFE surface is pretreated with hydrogen ion beam, or with argon and hydrogen ion beam, binding energy for CF binding barely peaked around 292 eV. That is, when the PTFE surface is pretreated with hydrogen ion beam, or with argon and hydrogen ion beam, peaks of binding energy for CF binding were 3×10⁴ CPS or less around 292 eV.

Therefore, it can be verified through the above results that, as the surface of the fluorine-based polymer is pretreated with hydrogen, or argon and hydrogen to selectively remove fluorine, the water contact angle can be lowered and adhesion to the coated layer can also be enhanced.

4. Low Dielectric Polymer Substrate with Deposition of Metal Coated Layer after Ion Beam Pretreatment Per Gas Type

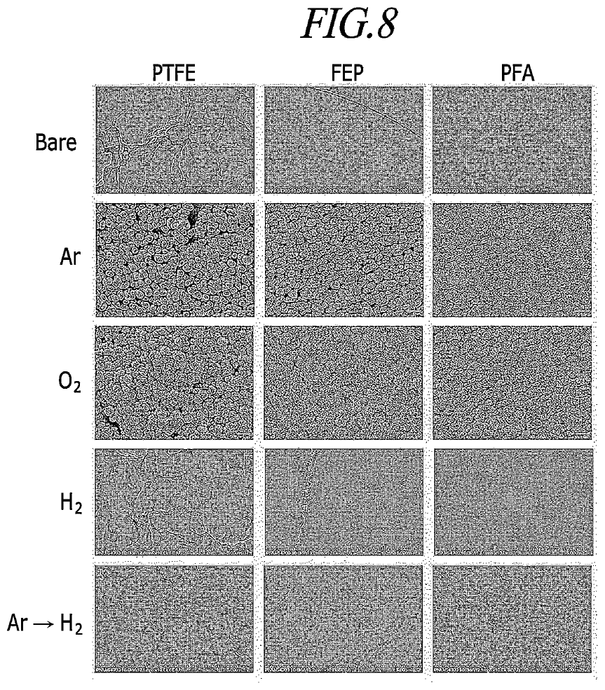

FIG. 8 is an image showing the surface structure of the metal layer of the low dielectric polymer substrate according to one embodiment of the present disclosure.

Referring to FIG. 8, it can be verified that the surface structure is flat when copper is deposited on a PTFE, FEP or PFA substrate that is treated with hydrogen ion beam or treated with hydrogen ion beam after treatment with argon ion beam treatment. On the other hand, it can be verified that the surface structure is not flat due to formation of a protrusion-shaped structure when copper is deposited on a PTFE, FEP or PFA substrate that is treated with oxygen ion beam or argon ion beam.

Accordingly, hydrogen ion beam treatment of the low dielectric polymer substrate of the present disclosure that is applicable to a Flexible Copper Clad Laminated Substrate may be suitable for maintaining flatness of the surface shape, and hydrogen ion beam treatment after argon ion beam treatment may be the more suitable for maintaining flatness of the surface shape.

5. Evaluation of Adhesion of Low Dielectric Polymer Substrate with Deposition of Metal Coated Layer after Ion Beam Pretreatment Per Gas Type

Copper is deposited after ion beam treatment of surface of the substrate of PTFE, a low dielectric polymer, by using different types of gases.

Subsequently, ASTM D 4541 Pull-off test, Cross cut test and 90° peeling test are proceeded for evaluation of adhesion between the PTFE substrate and the copper coated layer.

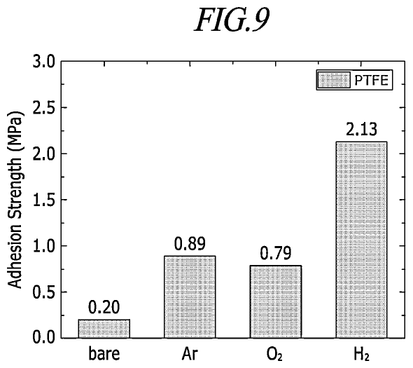

FIG. 9 is a graph showing test results of adhesion of the low dielectric polymer substrate according to one embodiment of the present disclosure.

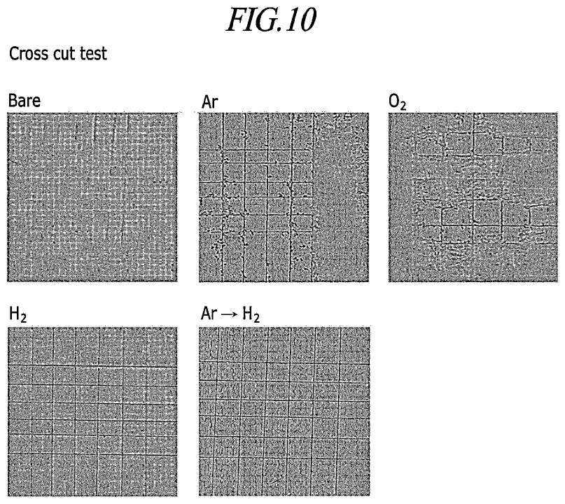

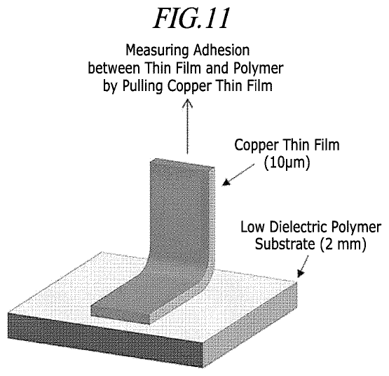

FIG. 10 is an image showing Cross Cut test results of the low dielectric polymer substrate according to one embodiment of the present disclosure.

FIG. 9 is an evaluation result of adhesion by ASTM D 4541 Pull-off test. Referring to FIG. 9, it is shown that adhesion between the low dielectric polymer substrate and copper coated layer is stronger when the substrate is treated with hydrogen ion beam than when the surface of the PTFE substrate is not treated with ion beam or when the surface of the PTFE substrate is treated with argon or oxygen.

FIG. 10 is the evaluation result of adhesion by Cross Cut test using tesa #7475. Referring to FIG. 10, it can be demonstrated that the copper coated layer is peeled off a lot in the case of no ion beam treatment of the PTFE substrate surface and in the case of argon or oxygen ion beam treatment of the PTFE substrate surface. On the other hand, it can be demonstrated that the copper coated layer is barely peeled off in the case of hydrogen ion beam treatment of the PTFE substrate surface and in the case of hydrogen ion beam treatment after argon ion beam treatment of the PTFE substrate surface.

FIG. 11 is a diagram schematically illustrating 90° peeling test method of the low dielectric polymer substrate according to one embodiment of the present disclosure.

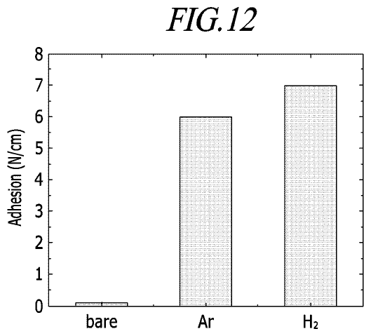

FIG. 12 is an image of 90° peeling test results of the low dielectric polymer substrate according to one embodiment of the present disclosure.

300 nm thick copper is sputter coated on the surface modified PTFE substrate by ion beam pretreatment and on the PTFE substrate without ion beam treatment. Then, 90° peeling test proceeded after electroplating of 10 μm thick copper for evaluation of adhesion between the PTFE substrate and the copper coated layer.

Referring to FIG. 12, the adhesion between the PTFE substrate without ion beam pretreatment and the copper coated layer was 0.1 N/cm or less, which was a result that can barely be evaluated. On the other hand, it is shown that the adhesion between the hydrogen ion beam pretreated PTFE substrate and the copper coated layer was 7 N/cm, which is not only significantly higher than the case of no ion beam pretreatment, but also higher than the case of argon ion beam pretreatment.

Accordingly, it was demonstrated that formation of the coated layer after hydrogen ion beam treatment of the low dielectric polymer substrate can enhance adhesion between the polymer layer and the coated layer, and that formation of the coated layer on the low dielectric polymer substrate that is hydrogen ion beam treated after argon ion beam treatment can further enhance the adhesion between the polymer layer and the coated layer.

As described above, embodiments of the present disclosure are described. However, anyone ordinarily skilled in the art to which the present disclosure pertains shall appreciate that there may be variety of modifications and permutations of the present disclosure by addition, modification, or deletion without departing from the technical ideas and scopes of the present disclosure that are defined in the appended claims and that these are also included in the scope of the present disclosure.

### DESCRIPTION OF REFERENCE NUMERALS

10: low dielectric polymer layer
12: surface modified layer
20: coated layer

What is claimed is:

1. A low dielectric polymer substrate comprising a low dielectric polymer layer;
a surface modified layer formed by ion beam pretreatment of surface of the polymer layer;
and a metal or ceramic coated layer optionally formed on the surface modified layer, wherein a water contact angle of the surface modified layer is 90° or less.

2. The low dielectric polymer substrate of claim 1, wherein the low dielectric polymer layer comprises at least one species of Polytetrafluoroethylene (PTFE), Perfluoroalkoxy (PFA), Ethylene Tetrafluoroethylene (ETFE), Fluorinated Ethylene Propylene (FEP), Polyvinylidene Fluoride (PVDF), Modified polyimide (MPI), Polyphenylene Sulfide (PPS), Olefin, and Liquid crystal polymer (LCP).

3. The low dielectric polymer substrate of claim 1, wherein dielectric constant of the low dielectric polymer layer is 4 or less.

4. The low dielectric polymer substrate of claim 1, wherein the low dielectric polymer layer has thickness of 0.01 mm or more to less than 2 mm.

5. The low dielectric polymer substrate of claim 1, wherein the ion beam pretreatment is an ion beam treatment that uses hydrogen gas; helium gas; or argon gas and hydrogen gas.

6. The low dielectric polymer substrate of claim 1, wherein the metal is at least one species of Cu, Ni, Cr and Ti.

7. The dielectric polymer substrate of claim 1, wherein the ceramic is at least one species of ZnO and Indium tin oxide (ITO).

8. A product comprising the low dielectric polymer substrate according to claim 1.

9. A preparation method of a low dielectric polymer substrate comprising ion beam pretreating for surface modification of a surface of a low dielectric polymer layer; and optionally forming a metal or ceramic coated layer on the polymer layer, wherein ion beam energy of the ion beam pretreating is 50 to 2000 eV.

10. The preparation method of claim 9, wherein the low dielectric polymer layer comprises at least one species of Polytetrafluoroethylene (PTFE), Perfluoroalkoxy (PFA), Ethylene Tetrafluoroethylene (ETFE), Fluorinated Ethylene Propylene (FEP), Polyvinylidene Fluoride (PVDF), Modified Polyimide (MPI), Polyphenylene Sulfide (PPS), Olefin and Liquid crystal polymer (LCP).

11. The preparation method of a low dielectric polymer substrate of claim 9, wherein gas used for the ion beam pretreating is hydrogen gas; helium gas; or argon gas and hydrogen gas.

12. The preparation method of a low dielectric polymer substrate of claim 9, wherein, when gas used for the ion beam pretreating is hydrogen, applied electrical power per ion beam speed is 2 kW/mpm or less.

13. The preparation method of a low dielectric polymer substrate of claim 9, wherein, when the thickness of the low dielectric polymer layer is 0.01 or more to less than 2 mm, applied voltage for the ion beam pretreating is 0.5 or more to less than 2 kV.

14. The preparation method of a low dielectric polymer substrate of claim 9, wherein the metal or ceramic coated layer is formed by sputtering deposition or ion beam assisted sputtering deposition.

15. The preparation method of a low dielectric polymer substrate of claim 9, wherein the preparation method proceeds in a roll-to-roll processing manner.

16. The preparation method of a low dielectric polymer substrate of claim 15, wherein a processing rate of the role-to-role processing is 0.1 to 10 mpm.
